(19) United States
(12) Patent Application Publication
(10) Pub. No.: US 2025/0255113 A1
(43) Pub. Date: Aug. 7, 2025

(54) ELECTRO-OPTICAL DEVICE AND ELECTRONIC APPARATUS

(71) Applicant: SEIKO EPSON CORPORATION, Tokyo (JP)

(72) Inventor: Hitoshi OTA, Shiojiri-shi (JP)

(73) Assignee: SEIKO EPSON CORPORATION, Tokyo (JP)

(21) Appl. No.: 19/045,030

(22) Filed: Feb. 4, 2025

(30) Foreign Application Priority Data
Feb. 5, 2024 (JP) 2024-015469

(51) Int. Cl. H10K 59/122; H10K 59/123

(52) U.S. Cl. CPC H10K 59/122; H10K 59/123

(57) ABSTRACT

An electro-optical device includes a substrate, a pixel electrode, a common electrode, a light-emitting function layer provided between the pixel electrode and the common electrode, a partition wall having conductivity, being in contact with the common electrode, and surrounding the pixel electrode, the light-emitting function layer, and the common electrode in plan view, a conductive layer provided between the partition wall and the substrate, a constant potential being supplied to the conductive layer, and an insulating layer provided between the partition wall and the conductive layer in cross-sectional view and including a contact hole for electrically coupling the partition wall to the conductive layer.

The present application is based on, and claims priority from JP Application Serial Number 2024-015469, filed Feb. 5, 2024, the disclosure of which is hereby incorporated by reference herein in its entirety.

### BACKGROUND

### 1. Technical Field

The present disclosure relates to an electro-optical device and an electronic apparatus.

### 2. Related Art

An electro-optical device using, for example, an OLED as a display element is known. OLED is an abbreviation for Organic Light Emitting Diode. Such a light-emitting element has a configuration in which a light-emitting function layer is interposed between a pixel electrode and a common electrode. The common electrode is required to be transparent, and a conductive material having transparency generally tends to have a large resistance component. Therefore, there is known technology for surrounding a pixel electrode, a light-emitting function layer, and a common electrode with a partition wall having conductivity in plan view, and applying a voltage to the common electrode through the conductivity.

### CITATION LIST

### Patent Literature

[PTL 1] JP-A-2023-100414

However, when there is a resistance component in the partition wall, not only electric power is wastefully consumed by the resistance component, but also the voltage applied to the common electrode (first electrode) fluctuates depending on a position of a display region. When the voltage applied to the common electrode fluctuates, there is a problem in that the fluctuation appears as unevenness in the display region and display quality is degraded.

### SUMMARY

In order to achieve the object, an electro-optical device according to an aspect of the present disclosure includes a substrate, a pixel electrode, a first electrode, a light-emitting function layer provided between the pixel electrode and the first electrode, a partition wall having conductivity, being in contact with the first electrode, and surrounding the pixel electrode, the light-emitting function layer, and the first electrode in plan view, a conductive layer provided between the partition wall and the substrate, a constant potential being supplied to the conductive layer, and a first insulating layer provided between the partition wall and the conductive layer in cross-sectional view and including a contact hole configured to electrically couple the partition wall to the conductive layer.

### BRIEF DESCRIPTION OF THE DRAWINGS

FIG. 1 is a perspective view illustrating a configuration of an electro-optical device according to a first embodiment.

FIG. 2 is a diagram illustrating an electrical configuration of the electro-optical device.

FIG. 3 is a diagram illustrating a configuration of a pixel circuit in the electro-optical device.

FIG. 4 is a diagram illustrating an operation of the electro-optical device.

FIG. 5 is a plan view illustrating main portions of the pixel circuit in the electro-optical device.

FIG. 6 is a cross-sectional view schematically illustrating the electro-optical device.

FIG. 7 is a cross-sectional view schematically illustrating a configuration of the main portions of the electro-optical device.

FIG. 8 is a cross-sectional view schematically illustrating a configuration of the main portions of the electro-optical device.

FIG. 9 is a cross-sectional view schematically illustrating an electro-optical device according to a second embodiment.

FIG. 10 is a cross-sectional view schematically illustrating an electro-optical device according to a third embodiment.

FIG. 11 is a perspective view illustrating a head-mounted display using the electro-optical device.

FIG. 12 is a diagram illustrating an optical configuration of the head-mounted display.

### DESCRIPTION OF EMBODIMENTS

Hereinafter, an electro-optical device according to an embodiment will be described with reference to the accompanying drawings. In each figure, dimensions and scales of respective portions are appropriately different from actual ones. Further, since embodiments to be described below are preferred specific examples, various technically preferable limitations are applied, but the scope of the present disclosure is not limited to these embodiments unless it is otherwise stated in the following description that the present disclosure is limited.

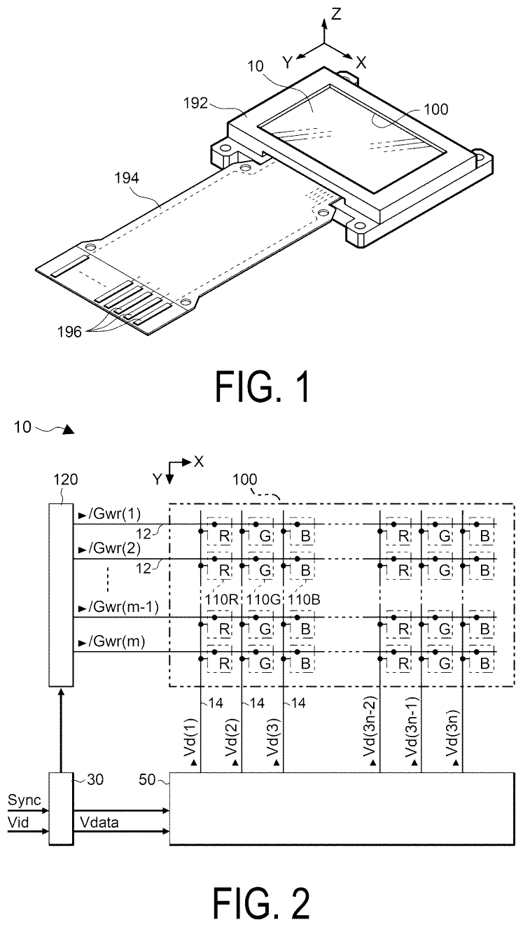

FIG. 1 is a perspective view illustrating an electro-optical device 10 according to a first embodiment, and FIG. 2 is a block diagram illustrating an electrical configuration of the electro-optical device 10.

The electro-optical device 10 is a micro display panel that displays a color image in a head-mounted display or the like, for example. The electro-optical device 10 includes, for example, a plurality of pixel portions and a driving circuit that drives the pixel portions. The pixel portions and the driving circuit are integrated on a semiconductor substrate. The semiconductor substrate is typically a silicon substrate, but may be another semiconductor substrate.

The electro-optical device 10 is accommodated in a frame-shaped case 192 that opens in a display region 100. One end of an FPC substrate 194 is coupled to the electro-optical device 10. FPC is an abbreviation for Flexible Printed Circuit. A plurality of terminals 196 for coupling a host device, which is not illustrated, are provided on the other end of the FPC substrate 194. When the plurality of terminals 196 are coupled to the host device, video data, synchronization signals, and the like are supplied from the host device to the electro-optical device 10 via the FPC substrate 194.

As illustrated in FIG. 2, the electro-optical device 10 is substantially divided into a control circuit 30, a data signal output circuit 50, the display region 100, and a scanning line driving circuit 120.

In the display region 100, m rows of scanning lines 12 are provided along an X direction, and (3n) columns of data lines 14 are provided along a Y direction and are electrically insulated from the scanning lines 12. m is an integer equal to or greater than 2, and n is an integer equal to or greater than 2.

To generalize and explain the scanning lines 12, an integer i equal to or greater than 1 and equal to or smaller than m is used. To distinguish the rows of the scanning lines 12, the rows may be called first, second, third, . . . , i-th, . . . , (m-1)-th, and m-th row from the top in the figure.

Similarly, to generalize and explain the data lines 14, an integer j equal to or greater than 1 and equal to or smaller than n is used. To distinguish the columns of the data lines 14, the columns may be called first, second, third, . . . (3j-2)-th, (3j-1)-th, (3j)-th,., (3n-2)-th, (3n-1)-th, and (3n)-th column from the left in the figure.

In the display region 100, pixel portions 110R that emit light in a red wavelength range, pixel portions 110G that emit light in a green wavelength range, and pixel portions 110B that emit light in a blue wavelength range are provided as follows, to correspond to intersections of m rows of scanning lines 12 and (3n) columns of data lines 14.

The pixel portion 110R is provided to correspond to the intersection of the scanning line 12 of each row and the data line 14 of the (3j-2)-th column. The pixel portion 110G is provided to correspond to the intersection of the scanning line 12 of each row and the data line 14 of the (3j-1)-th column. The pixel portion 110B is provided to correspond to the intersection of the scanning line 12 of each row and the data line 14 of the (3j)-th column.

That is, in the display region 100, the pixel portions 110R, 110G, and 110B are arranged along the X direction, and the pixel portions 110 with the same color are arranged along the Y direction. Therefore, the pixel portions 110 with the same color correspond to any one column of the data lines 14. One color is expressed by additive color mixing of the three pixel portions 110R, 110G, and 110B adjacent in the X direction. Therefore, the electro-optical device 10 displays an image in which color pixels are arranged in m rows and n columns.

Strictly speaking, the pixel portions 110R, 110G, and 110B should be called sub-pixel portions, but are referred to as pixel portions for convenience of description. Further, when the pixel portions 110R, 110G, and 110B are generally described without specifying the color, the pixel portions 110R, 110G, and 110B will be described with a reference sign 110.

The control circuit 30 controls each portion based on video data Vid or a synchronization signal Sync supplied from a host device (not shown). Specifically, the control circuit 30 generates various control signals to control the respective portions.

The video data Vid designates, for example, a gradation level of a pixel in an image to be displayed by 8 bits. The synchronization signal Sync includes a vertical synchronization signal for giving an instruction for starting vertical scanning of the video data Vid, a horizontal synchronization signal for giving an instruction for starting horizontal scanning, and a dot clock signal that indicates a timing of one pixel of the video data.

Characteristics of luminance at a gradation level indicated by the video data Vid supplied from the host device do not necessarily match characteristics of luminance in the OLED included in the pixel portion 110. Therefore, in order to cause the OLED to emit light at a luminance corresponding to the gradation level indicated by the video data Vid, the control circuit 30 upconverts the 8 bits of the video data Vid to, for example, 10 bits and outputs the video data Vid as video data Vdata. Therefore, the 10-bit video data Vdata becomes data corresponding to gradation levels of R, G, and B designated by the video data Vid.

For the upconversion, a lookup table in which a correspondence relationship between the 8 bits of the video data Vid, which is an input, and the 10 bits of the video data Vdata, which is an output, have been stored in advance is used.

The scanning line driving circuit 120 is a circuit for driving the pixel portion 110 arranged in m rows and (3n) columns for each row under the control of the control circuit 30. For example, the scanning line driving circuit 120 supplies scanning signals /Gwr(1), /Gwr(2), . . . , /Gwr(m-1), /Gwr(m) to the scanning lines 12 in the first, second, third, . . . , (m-1)-th, and m-th rows in order. In general, the scanning signal supplied to the scanning line 12 of an i-th row is denoted as /Gwr(i).

The data signal output circuit 50 is a circuit that outputs a data signal to the pixel portions 110 located in a row selected by the scanning line driving circuit 120 via the data line 14 under the control of the control circuit 30. The data signal is a voltage signal obtained by converting the 10-bit video data Vdata into an analog signal. In other words, the data signal output circuit 50 converts video data Vdata of one row corresponding to the pixel portions 110 of first to (3n)-th columns in the selected row into an analog type and outputs the analog type data to the data lines 14 of the first to (3n)-th columns in order.

Although not particularly illustrated, a power supply circuit is provided outside the display region 100, and the power supply circuit generates potentials Vel and Vct of power supplies of the control circuit 30, the scanning line driving circuit 120, the data signal output circuit 50, and the OLED.

Further, in the figure, the data signals output to the data lines 14 in the first, second, third, . . . , (3n-2)-th, (3n-1)-th, and (3n)-th columns are represented as Vd(1), Vd(2), Vd(3), . . . , Vd(3n-2), Vd(3n-1), and Vd(3n) in order. In general, for example, a potential of the data line 14 in the (3j-2)-th column is represented as Vd(3j-2).

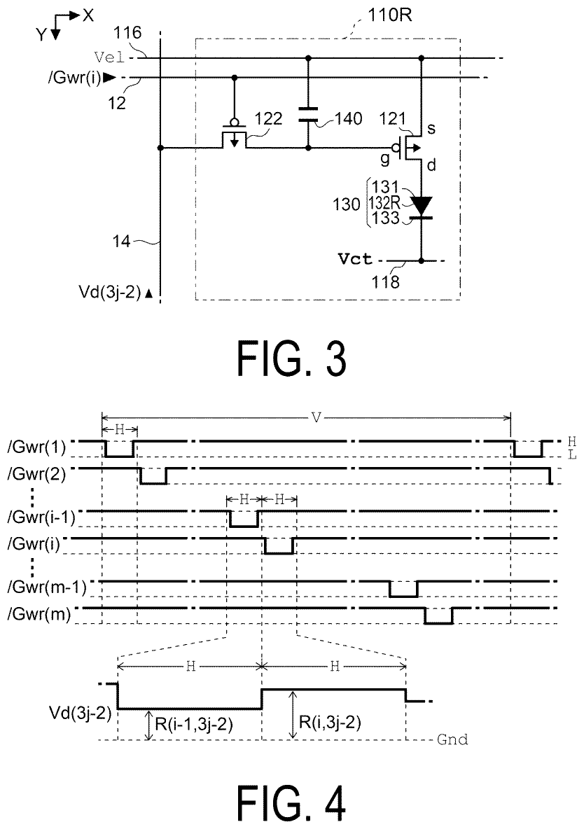

FIG. 3 is a diagram illustrating an electrical configuration of the pixel portion in the electro-optical device 10.

Electrically, the pixel portions 110R, 110G, and 110B have the same configuration. Therefore, the electrical configuration of the pixel portions 110R, 110G, and 110B will be described using the pixel portion 110R corresponding to the i-th row and (3j-2)-th column as an example.

As shown in the figure, the pixel portion 110R includes, from an electrical perspective, P-channel MOS type transistors 121 and 122, an OLED 130, and a capacitance element 140.

In the description of the pixel portion, “from an electrical perspective” is used to refer to a plurality of elements constituting the pixel portion and a coupling relationship between the plurality of elements.

The OLED 130 of the pixel portion 110R sandwiches a light-emitting function layer 132R between a pixel electrode 131 and a common electrode 133. The light-emitting function layer 132R emits light including an R wavelength range. The pixel electrode 131 functions as an anode, and the common electrode 133 functions as a cathode. In the OLED 130, when a current flows from the anode to the cathode, holes injected from the anode and electrons injected from the cathode are recombined in the light-emitting function layer 132R so that excitons are generated and the light including the R wavelength range is generated.

In the transistor 121 of the pixel portion 110R in the i-th row and the (3j-2)-th column, a gate node g is coupled to a drain node of the transistor 122, a source node is coupled to a power supply line 116 for a potential Vel, and a drain node is coupled to the pixel electrode 131 which is the anode of the OLED 130.

In the transistor 122 of the pixel portion 110R in the i-th row and the (3j-2)-th column, a gate node is coupled to the scanning line 12 in the i-th row, and a source node is coupled to the data line 14 in the (3j-2)-th column. The common electrode 133 functioning as the cathode of the OLED 130 is coupled to a power supply line 118 for a potential Vct. Further, since the electro-optical device 10 is formed at a silicon substrate, a substrate potential of the transistors 121 and 122 is set to, for example, a potential equivalent to the potential Vel.

The pixel portion 110R illustrated in FIG. 3, and the pixel portions 110G and 110B are electrically common. However, the light-emitting function layer 132R is replaced by a light-emitting function layer 132G that emits light including a G wavelength range in the pixel portion 110G, and is replaced by a light-emitting function layer 132B that emits light including a B wavelength range in the pixel portion 110B.

In FIG. 1, FIG. 2, and FIG. 3, the X direction is a direction in which the scanning line 12 extends in the electro-optical device 10, and is a horizontal direction in terms of the display screen, and the Y direction is a direction in which the data line 14 extends, and is a vertical direction in terms of the display screen. A two-dimensional plane determined by the X direction and the Y direction is a substrate surface of a semiconductor substrate. A Z direction in FIG. 1 is perpendicular to the X direction and the Y direction, and is an emission direction of the light emitted from the OLED 130. Further, in the present description, a plan view refers to a view of the semiconductor substrate from an opposite direction to the Z direction, and a cross-sectional view refers to a view of the semiconductor substrate cut in a direction perpendicular to a substrate surface.

FIG. 4 is a timing chart illustrating an operation of the electro-optical device 10.

In the electro-optical device 10, m rows of scanning lines 12 are scanned one by one in an order of first, second, third, . . . , m-th rows during a period of a frame (V). In detail, as shown in the figure, scanning signals /Gwr(1), /Gwr(2), . . . , /Gwr(m-1), and /Gwr(m) are sequentially and exclusively set to an L level for each horizontal scanning period (H) by the scanning line driving circuit 120.

In the present embodiment, periods during which adjacent scanning signals among the scanning signals /Gwr(1) to /Gwr(m) are set to the L level are separated in time. Specifically, after the scanning signal /Gwr(i-1) changes from L level to H level, the next scanning signal /Gwr(i) goes to L level after a period. This period corresponds to the horizontal blanking period.

In this description, a period of one frame (V) refers to a period required to display one frame of an image designated by the video data Vid. In a case in which a length of the period of one frame (V) is the same as a vertical synchronization period, for example, when a frequency of a vertical synchronization signal included in the synchronization signal Sync is 60 Hz, it is 16.7 milliseconds, which corresponds to one cycle of the vertical synchronization signal. Further, the horizontal scanning period (H) is an interval of time in which the scanning signals /Gwr(1) to /Gwr(m) reach the L level in order, but in the drawing, for convenience, a start timing of the horizontal scanning period (H) is approximately a center of the horizontal return period.

When a scanning signal among the scanning signals /Gwr(1) to /Gwr(m), for example, the scanning signal /Gwr(i) supplied to the scanning line 12 of the i-th row, becomes at the L level, and in the case of the (3j-2)-th column, the transistor 122 enters the ON state in the pixel portion 110R of the i-th row and the (3j-2)-th column, for example. Therefore, the gate node g of the transistor 121 in the pixel portion 110R is electrically coupled to the data line 14 of the (3j-2)-th column.

In the present description, the “ON state” of the transistor means that a space between the source node and the drain node in the transistor is electrically closed to be in a low impedance state. Also, an “OFF state” of the transistor means that the space between the source node and the drain node is electrically opened to be in a high impedance state.

Further, in this description, “electrically coupled” or simply “coupled” means a state in which two or more elements are directly or indirectly coupled or joined. “Electrically non-coupled” or simply “non-coupled” means a state in which two or more elements are not directly or indirectly coupled or joined.

In the horizontal scanning period (H) in which the scanning signal /Gwr(i) becomes at a L level, the data signal output circuit 50 converts the video data Vdata decomposed into R, G, and B into analog potentials Vd(1) to Vd(3n) and outputs the potentials as data signals to the data lines 14 in the first to (3n)-th columns.

The video data Vdata decomposed into R, G, and B is three primary color components of the gradation level of the pixels in the first row and the first column to the i-th row and the n-th column indicated by the video data Vid.

In the case of the (3j-2)-th column, the data signal output circuit 50 converts a gradation level R (i, j) of R among the pixels in the i-th row and the j-th column indicated by the video data Vid into an analog signal potential Vd(3j-2) and outputs the potential as a data signal to the data line 14 in the (3j-2)-th column.

In the horizontal scanning period (H) in which the scanning signal /Gwr(i-1) one line before the scanning signal /Gwr(i) becomes at a L level, the data signal output circuit 50 converts a gradation level R(i-1, j) of R among the pixels in a (i-1)-th row and the j-th column into an analog signal potential Vd(3j-2) and outputs the potential as a data signal to the data line 14 in the (3j-2)-th column.

The data signal at the potential Vd(3j-2) is applied to the gate node g of the transistor 121 in the pixel portion 110R in the i-th row and the (3j-2)-th column via the data line 14 in the (3j-2)-th column, and the potential Vd(3j-2) is held by the capacitance element 140. Therefore, the transistor 121 causes a current corresponding to a voltage between the gate node and the source node to flow to the OLED 130.

Even when the scanning signal Gwr(i) becomes at a H level and the transistor 122 is turned off, the potential Vd(3j-2) is held by the capacitance element 140, so that a current continues to flow through the OLED 130. Therefore, in the pixel portion 110R in the i-th row and the (3j-2)-th column, the OLED 130 continues to emit light at the voltage held by the capacitance element 140, that is, at a brightness corresponding to the gradation level, until the period of the one frame (V) has elapsed and the transistor 122 is turned on again so that a voltage of the data signal is applied again.

Although the pixel portion 110R in the i-th row and the (3j-2)-th column has been described here, the OLEDs 130 of the pixel portions 110R, 110G, and 110B in columns other than the (3j-2)-th column in the i-th row also emit light at the luminance indicated by the video data Vdata.

The OLEDs 130 of the pixel portions 110R, 110G, and 110B in rows other than the i-th row also emit light at the luminance indicated by the video data Vdata as the scanning signals /Gwr(1) to /Gwr(m) sequentially become at the L level.

Therefore, in the electro-optical device 10, during the period of the one frame (V), the OLEDs 130 of all the pixel portions 110R, 110G, and 110B from the first row and the first column to the m-th row and the (3n)-th column emit light at the luminance indicated by the video data Vdata to display one frame of image.

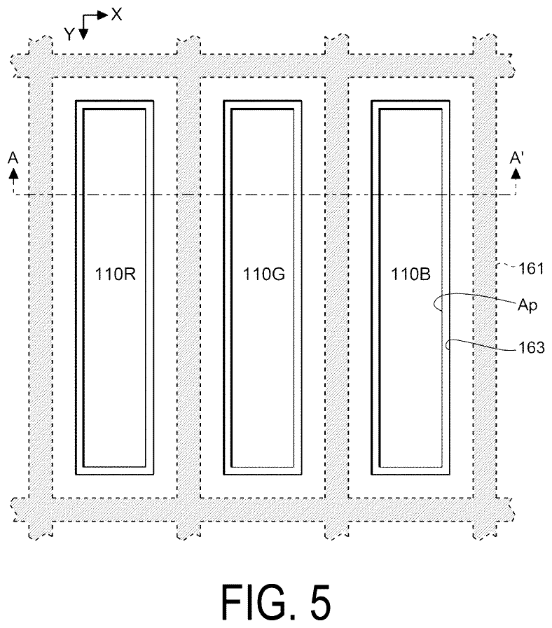

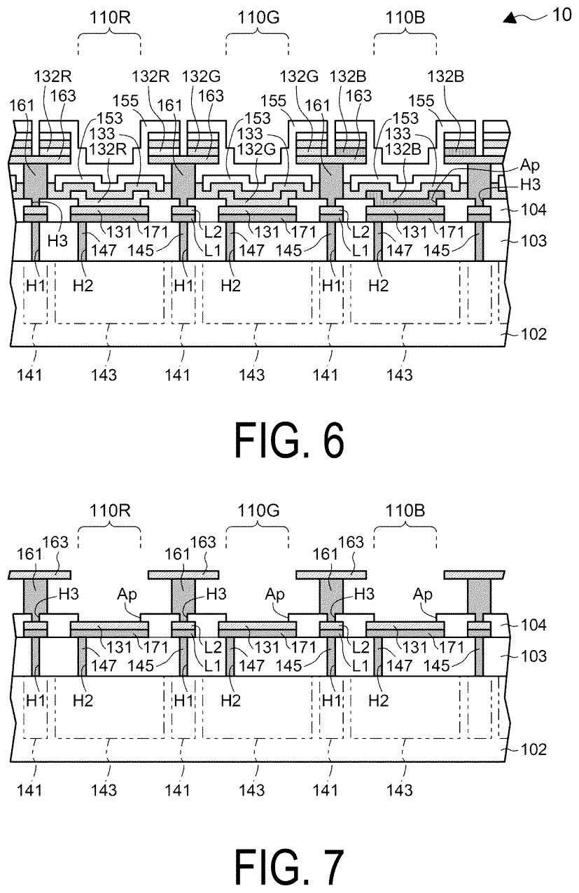

FIG. 5 is a plan view illustrating disposition of the pixel portions 110R, 110G, and 110B in the electro-optical device 10, and FIG. 6 is a cross-sectional view of main portions taken along line A-A′ in FIG. 5.

As illustrated in FIG. 5, the pixel portions 110R, 110G, and 110B are repeatedly arranged in this order in the X direction in plan view.

In FIG. 6, a substrate 102 is a semiconductor substrate such as silicon. A conductive layer 141 and a circuit layer 143 are provided on the substrate 102.

The conductive layer 141 is a wiring layer for applying the potential Vct generated by the power supply circuit located outside the display region 100 to the common electrode 133, and constitutes part of the power supply line 116. The circuit layer 143 is provided to correspond to the pixel portion 110R, 110G, or 110B, and is provided with elements such as the transistors 121 and 122 and various wirings.

An insulating layer 103 is provided on the substrate 102. Contact holes H1 and H2 are provided in the insulating layer 103. The contact hole H1 is filled with a coupling member 145 such as tungsten, and the contact hole H2 is filled with a coupling member 147 such as tungsten.

After a reflective metal layer and a transparent conductive layer are stacked on the insulating layer 103 filled with the coupling members 145 and 147, both the layers are patterned. This patterning provides a stack of the reflective electrode 171 and the pixel electrode 131 and a stack of electrodes L1 and L2. The stack of the reflective electrode 171 and the pixel electrode 131 is provided for each of the pixel portions 110R, 110G, and 110B.

The reflective metal layer is a metal wiring layer having light reflectivity, such as aluminum, and the transparent conductive layer is a wiring layer having light transparency and conductivity, such as indium tin oxide (ITO).

The reflective electrode 171 comes into contact with the coupling member 147. Accordingly, the pixel electrode 131 is electrically coupled to the drain node of the transistor 121 included in the circuit layer 143 via the reflective electrode 171 and the coupling member 147.

Similarly, the electrode L1 comes into contact with the coupling member 145. Accordingly, the potential Vct is applied to the stack of the electrodes L1 and L2.

A pixel separation layer 104 having an insulating property is provided to cover the insulating layer 103, the reflective electrode 171, and the pixel electrode 131. Thereafter, openings Ap for exposing the pixel electrodes 131 and contact holes H3 for exposing electrodes L2 are provided in the pixel separation layer 104. Specifically, the opening Ap has a rectangular shape as illustrated in FIG. 5 in plan view, and is provided to overlap a peripheral edge of the pixel electrode 131 as illustrated in FIG. 6 in cross-sectional view. The contact hole H3 is provided to cause a partition wall 161, which will be described next, to couple to the stack of the electrodes L1 and L2.

FIG. 7 is a cross-sectional view illustrating a stage in which the partition wall 161 and an upper portion 163 are provided in a manufacturing process of the electro-optical device 10.

The partition wall 161 and the upper portion 163 are provided by, for example, collective patterning. Specifically, the partition wall 161 and the upper portion 163 are provided at boundaries of the adjacent pixel portions 110R, 110G, and 110B as shown by hatching in FIG. 5 in plan view, and are provided to overlap the electrodes L1 and L2 as illustrated in FIG. 6 or 7 in cross-sectional view.

When seen in plan view, the partition wall 161 and the upper portion 163 are provided in a lattice shape in a portion extending along the X direction and a portion extending along the Y direction. Therefore, the pixel portions 110R, 110G, and 110B are surrounded by the partition wall 161 and the upper portion 163 in plan view.

The partition wall 161 is made of a metal wiring layer having conductivity, such as aluminum. The upper portion 163 is a metal wiring layer having conductivity such as titanium, and is made of a material having an etching rate lower than the partition wall, that is, a material which is hard to be etched.

In the collective etching, since the etching of the partition wall 161 progresses faster than the etching of the upper portion 163, the upper portion 163 becomes wider than the partition wall 161 in plan view, and both ends of the upper portion 163 protrude from a side surface of the partition wall 161 in cross-sectional view.

Although the partition wall 161 and the upper portion 163 are provided to surround each of the pixel portions 110R, 110G, and 110B in plan view, the conductive layer 141, the contact holes H1 and H3, and the coupling member 145 do not need to surround the pixel portions 110R, 110G, and 110B, and may be provided between the light-emitting function layers in the pixel portions adjacent to each other in plan view. For example, the contact holes H1 and H3 and the coupling member 145 may be provided at points at which a portion extending along the X direction and a portion extending along the Y direction intersect with each other in the partition wall 161.

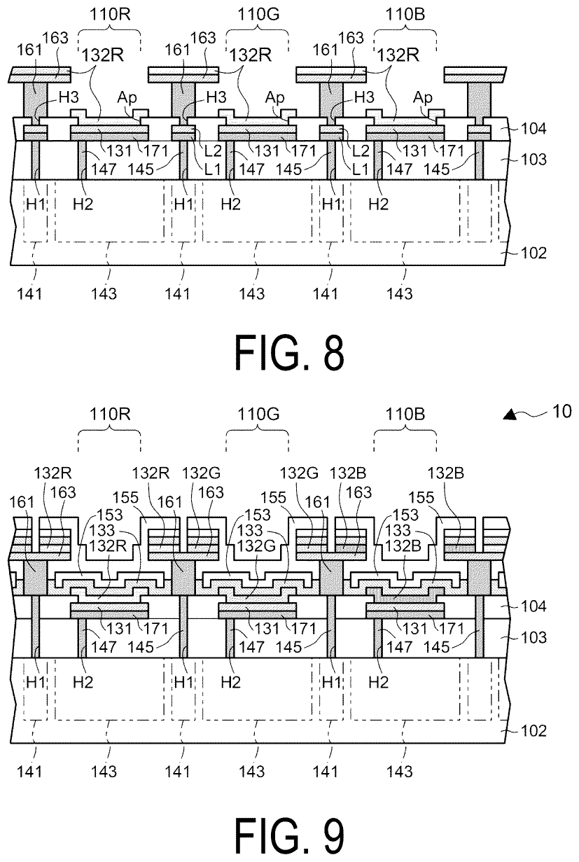

FIG. 8 is a cross-sectional view illustrating a state immediately after the light-emitting function layer 132R is formed in the manufacturing process of the electro-optical device 10.

As shown in this figure, the light-emitting function layer 132R is deposited from above in the figure. Therefore, the light-emitting function layer 132R is formed to cover the opening Ap of the pixel separation layer 104 in the pixel portion 110R, but is not formed in a portion of the pixel separation layer 104 blocked by the upper portion 163. That is, in the pixel portion 110R, the light-emitting function layer 132R are formed to overlap the pixel electrode 131 using the upper portions 163, which has been already provided, as a mask. Therefore, since the light-emitting function layer 132R is formed not by photolithography but by self-alignment, a resist coating step, an exposure step using a photomask, a developing step of removing an unnecessary resist, a step of etching a portion from which the resist has been removed, and a step of removing the resist are not necessary.

Although the light-emitting function layer 132R is also provided in the pixel portions 110G and 110B of different colors at this stage, the light-emitting function layer 132R is removed by subsequent etching.

The description will return to FIG. 6. After the light-emitting function layer 132R is formed, a conductive layer having transparency and conductivity, such as ITO, is formed so that the common electrode 133 is provided. The common electrode 133 is in contact with a sidewall of the partition wall 161. Therefore, the potential Vct is applied to the common electrode 133 via the conductive layer 141, the coupling member 145, the electrodes L1 and L2, and the partition wall 161 in this order.

After the common electrode is formed, a cap layer 153 having an insulating property and transparency is formed to include the opening Ap in plan view and cover the common electrode 133 in cross-sectional view.

The light-emitting function layer 132R, the same conductive layer as the common electrode 133, and the cap layer 153 are stacked in this order on an upper surface of the upper portion 163 surrounding the pixel portion 110R.

After the cap layer 153 is formed, a sealing layer 155 having an insulating property is provided to cover the display region 100.

At this stage, the common electrode 133, the cap layers 153, and the sealing layer 155 are provided to overlap the light-emitting function layer 132R on the light-emitting function layer 132R in the pixel portions 110G and 110B. In order to remove these and form the light-emitting function layer 132G of a correct color in the pixel portion 110G, the pixel portion 110R is first covered with a photoresist and protected. Thereafter, the light-emitting function layer 132R, the common electrode 133, the cap layer 153, and the sealing layer 155 in the pixel portions 110G and 110B are removed by etching so that the pixel electrode 131 is exposed.

In the pixel portion 110G, the light-emitting function layer 132G of G is formed by self-alignment using the upper portion 163 as a mask, and the common electrode 133, the cap layer 153, and the sealing layer 155 are provided to overlap each other, similarly to the pixel portion 110R.

At this stage, in the pixel portion 110B, the common electrode 133, the cap layer 153, and the sealing layer 155 are provided to overlap the light-emitting function layer 132G on the light-emitting function layer 132G.

In order to remove these and form the light-emitting function layer 132B of a correct color in the pixel portion 110B, the pixel portion 110G is covered with a photoresist and protected. Thereafter, the light-emitting function layer 132G, the common electrode 133, the cap layers 153, and the sealing layer 155 in the pixel portion 110B are removed by etching so that the pixel electrode 131 is exposed.

In the pixel portion 110B, the light-emitting function layer 132G of G is formed by self-alignment using the upper portion 163 as a mask, and the common electrode 133, the cap layer 153, and the sealing layer 155 are provided to overlap each other, similarly to the pixel portions 110R and 110G.

This results in a configuration as illustrated in FIG. 6.

In the figure, the light-emitting function layer 132, the same conductive layer as the common electrode 133, the same insulating layer as the cap layer 153, and the sealing layer 155 are stacked on the upper surface of the upper portion 163, but are separated in the vicinity of boundaries of the pixel portions 110R, 110G, and 100B. This separation is caused by etching due to the protection of the photoresist.

Thereafter, although not particularly illustrated, one or more sealing layers having an insulating property and a planarization layer are provided. In the electro-optical device 10, the light generated in the light-emitting function layers 132R, 132G, and 132B is reflected by the reflective electrodes 171 and emitted in the Z direction even when the light travels in a direction opposite to the Z direction.

In the electro-optical device 10 according to the embodiment, the potential Vct is applied to the common electrode 133 not only through a single path of the partition wall 161 but also through a path including the conductive layer 141, the coupling member 145, and the electrodes L1 and L2.

Therefore, according to the present embodiment, since the potential Vct is applied to the common electrode 133 via a plurality of electrically parallel paths, a resistance of a path from the power supply circuit to the common electrode 133 is reduced. Therefore, in the present embodiment, it is possible to curb the electric power consumed by a resistance component, and it is possible to achieve a high-quality display with curbed display unevenness since a distribution of the potential Vct of the common electrode 133 in the display region 100 is made uniform.

The common electrode 133 is an example of “first electrode”, the contact holes H1 are earth spirit of “contact hole”, and the insulating layer 103 is an example of “first insulating layer”. Further, the light-emitting function layer 132 when the color is not specified in the light-emitting function layers 132R, 132G, and 132B is an example of the “light-emitting function layer”.

The electrode L2 is an electrode formed by patterning the same conductive layer as the pixel electrode 131, and is made of the same material as the pixel electrode 131. The electrode L2 is an example of “first electrode” made of the same material as the pixel electrode 131, the electrode L1 is an example of “second electrode”, and the pixel separation layer 104 is an example of “second insulating layer”.

FIG. 9 is a cross-sectional view of main portions showing a configuration of the electro-optical device 10 according to a second embodiment. In the first embodiment illustrated in FIG. 6, the coupling member 145 filled in the contact hole H1 is configured to come into contact with the partition wall 161 via the electrodes L1 and L2. On the other hand, in the second embodiment, the contact hole H1 opens not only the insulating layer 103 but also the pixel separation layer 104, and the contact hole H1 is filled with the coupling member 145. That is, in the second embodiment, the coupling member 145 is configured to be in direct contact with the partition wall 161 without passing through the electrodes L1 and L2.

Therefore, in the second embodiment, since the electrodes L1 and L2 are not provided below the partition wall 161, it is possible to narrow the partition wall 161 in plan view to increase an area of the opening Ap, that is, to increase an aperture ratio of the pixel portions 110R, 110G, and 110B.

In the second embodiment, the contact hole H1 was configured to open the insulating layer 103 and the pixel separation layer 104. Apart from this configuration, although not particularly illustrated, a configuration in which the contact hole H1 opens only the insulating layer 103, the contact hole H1 is filled with the coupling member 145, the contact hole opening the pixel separation layer 104 is separately provided, and the partition wall 161 is filled through the contact hole may be adopted, similarly to the first embodiment. That is, this configuration is a configuration in which the electrodes L1 and L2 in FIG. 6 are removed and the contact hole H3 opening the pixel separation layer 104 is filled with a part of the partition wall 161.

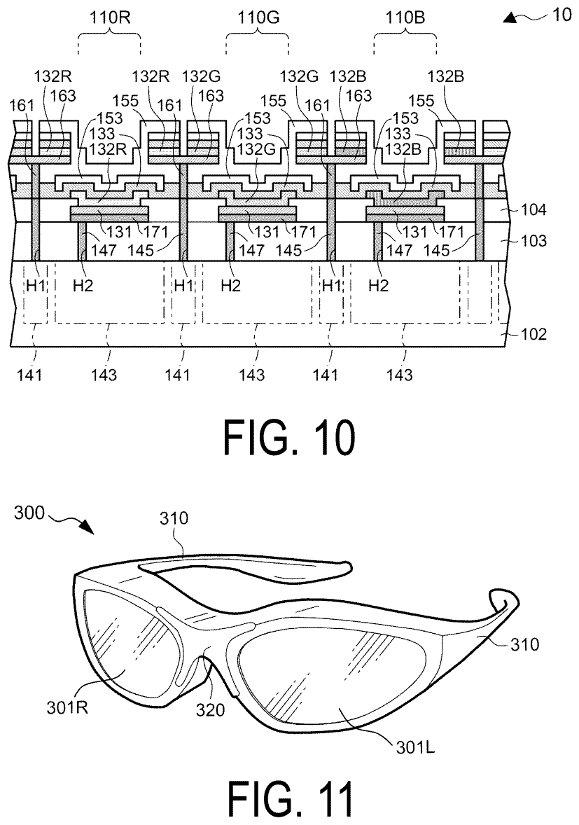

FIG. 10 is a cross-sectional view of main portions illustrating a configuration of the electro-optical device 10 according to the third embodiment.

In the third embodiment, a configuration in which the contact hole H1 opens the insulating layer 103 and the pixel separation layer 104, and the contact hole H1 is filled with the coupling member 145 is common to that of the second embodiment. However, in the third embodiment, the partition wall 161 is made of the same material as the coupling member 145 with which the contact hole H1 is filled, for example, tungsten.

According to the third embodiment, electrodes L1 and L2 are not provided below the partition wall 161, similarly to the second embodiment. Further, according to the third embodiment, since the partition wall 161 is made of the same material as that of the coupling member 145, it is possible to narrow the partition wall 161 in plan view, as compared to the second embodiment. Therefore, in the third embodiment, it is possible to increase the aperture ratio of the pixel portions 110R, 110G, and 110B by increasing the area of the opening Ap.

In the first to third embodiments described above (hereinafter referred to as an “embodiment and the like”), various variations or applications can be made as follows.

In the embodiment and the like, an opening shape of the opening Ap in the pixel portions 110R, 110G, and 110B is rectangular, but the present disclosure is not limited thereto. For example, the opening shape may be hexagonal or the like. Further, the opening area of the opening Ap may not be uniform in the pixel portions 110R, 110G, and 110B, but may be different for each color. For example, the opening area of the opening Ap may be G>R>B.

The pixel portions 110R, 110G, and 110B may be aligned in the X direction or in the Y direction. Further, the pixel portions 110R and 110B may be arranged in the same column, and the pixel portion 110G may be arranged in a column adjacent to the column of the pixel portions 110R and 110B.

In the embodiment and the like, the light-emitting function layers 132R, 132G, and 132B are formed in this order, but an order of the film formation is not limited thereto.

Next, an electronic apparatus to which the electro-optical device 10 according to the embodiment and the like is applied will be described. The electro-optical device 10 is suitable for application of a small pixel size and high definition display. Consequently, a head-mounted display will be described as an example of the electronic apparatus.

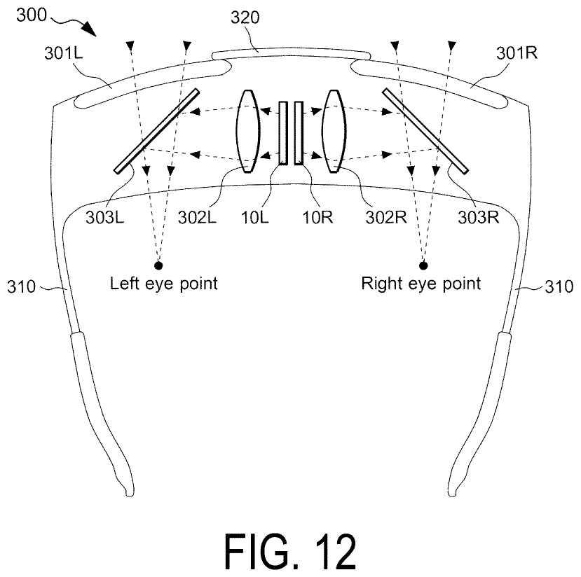

FIG. 11 is a diagram illustrating an appearance of a head-mounted display, and FIG. 12 is a diagram illustrating an optical configuration thereof.

First, as illustrated in FIG. 11, a head-mounted display 300 includes temples 310, a bridge 320, and lenses 301L and 301R in appearance, similar to general eyeglasses. Further, as illustrated in FIG. 12, the head-mounted display 300 has an electro-optical device 10L for a left eye and an electro-optical device 10R for a right eye are provided near the bridge 320 and on the rear side (lower side in the figure) of the lenses 301L and 301R.

An image display surface of the electro-optical device 10L is disposed to be on the left side in FIG. 12. Thus, a display image in the electro-optical device 10L is emitted in a 9-o'clock direction in the figure via the optical lens 302L. A half mirror 303L reflects the display image in the electro-optical device 10L in a 6-o'clock direction, and transmits light incident from a 12-o'clock direction. An image display surface of the electro-optical device 10R is disposed to be on the right side opposite to the electro-optical device 10L. Thus, a display image in the electro-optical device 10R is emitted in a 3-o'clock direction in the figure via the optical lens 302R. A half mirror 303R reflects the display image in the electro-optical device 10R in a 6-o'clock direction, and transmits light incident from a 12-o'clock direction.

In this configuration, a wearer of the head-mounted display 300 can observe the display image in the electro-optical devices 10L and 10R in a see-through state in which the display image is overlapped with the outside.

Further, in the head-mounted display 300, when an image for a left eye between images for both eyes involving parallax is displayed by the electro-optical device 10L, and an image for a right eye is displayed by the electro-optical device 10R, it is possible to cause the wearer to perceive the displayed image as having depth or stereoscopic effect.

The electronic apparatus including the electro-optical device 10 can be applied not only to the head-mounted display 300 but also to an electronic viewfinder in a video camera, a lens-interchangeable digital camera, or the like, a display unit of a smartwatch or a wearable device, a light valve of a projection-type projector, or the like. Further, the present disclosure is not limited to the display unit, and can be applied to a surface light-emitting element having a matrix light-emitting source, specifically, a backlight, an optical communication element, or the like.

From the embodiments illustrated above, the following aspects can be ascertained, for example. Hereinafter, in order to facilitate understanding of each of the aspects, the reference signs of the drawings are provided in parentheses for convenience, but the present disclosure is not intended to be limited to the illustrated aspects.

An electro-optical device (10) according to aspect 1 includes a substrate (102), a pixel electrode (131), a first electrode (133), a light-emitting function layer (132) provided between the pixel electrode (131) and the first electrode (133), a partition wall (161) having conductivity, being in contact with the first electrode (133), and surrounding the pixel electrode (131), the light-emitting function layer (132), and the first electrode (133) in plan view, a conductive layer (141) provided between the partition wall (161) and the substrate (102), a constant potential being supplied to the conductive layer, and a first insulating layer (103) provided between the partition wall (161) and the conductive layer (141) in cross-sectional view and including a contact hole (H1) for electrically coupling the partition wall (161) to the conductive layer (141).

According to the electro-optical device of aspect 1, since the first electrode is in contact with the partition wall and the contact hole for electrically coupling the partition wall to the conductive layer is provided in the first insulating layer between the partition wall and the conductive layer, it is possible to reduce the resistance through a double wiring with the conductive layer in addition to the partition wall.

In an electro-optical device (10) according to specific aspect 2 of aspect 1, the partition wall (161) is electrically coupled to the conductive layer (141) via a first electrode (L1) made of the same material as the pixel electrode (131).

In an electro-optical device (10) according to another specific aspect 3 of aspect 1, a second electrode (171) having reflectivity is provided between the pixel electrode (131) and the first insulating layer (103).

An electro-optical device (10) according to another specific aspect 4 of aspect 1 further includes a second insulating layer (104) having an insulating property and overlapping the pixel electrode (131) to open the pixel electrode (131).

In an electro-optical device (10) according to specific aspect 5 of aspect 4, the contact hole (H1) opens the first insulating layer (103) and the second insulating layer (104), and the partition wall (161) is electrically coupled to the conductive layer (141) via a coupling member (145) provided in the contact hole (H1).

In an electro-optical device (10) according to specific aspect 6 of aspect 5, the partition wall (161) is made of the same material as the coupling member (145).

In an electro-optical device (10) according to another specific aspect 7 of aspect 1, the conductive layer (141) is provided between light-emitting function layers (132) adjacent to each other in plan view.

In an electro-optical device (10) according to another specific aspect 8 of aspect 1, the contact hole (H1) is provided between light-emitting function layers (132) adjacent to each other in plan view.

An electronic apparatus (300) according to aspect 9 includes the electro-optical device (10) according to any one of aspects 1 to 8.

What is claimed is:

1. An electro-optical device comprising:
a substrate;
a pixel electrode;
a first electrode;
a light-emitting function layer provided between the pixel electrode and the first electrode;
a partition wall having conductivity, being in contact with the first electrode, and surrounding the pixel electrode, the light-emitting function layer, and the first electrode in plan view;
a conductive layer provided between the partition wall and the substrate, a constant potential being supplied to the conductive layer; and
a first insulating layer provided between the partition wall and the conductive layer in cross-sectional view and including a contact hole configured to electrically couple the partition wall to the conductive layer.

2. The electro-optical device according to claim 1, wherein
the partition wall is electrically coupled to the conductive layer via a first electrode made of the same material as the pixel electrode.

3. The electro-optical device according to claim 1, wherein
a second electrode having reflectivity is provided between the pixel electrode and the first insulating layer.

4. The electro-optical device according to claim 1, comprising:
a second insulating layer having an insulating property and overlapping the pixel electrode to open the pixel electrode.

5. The electro-optical device according to claim 4, wherein
the contact hole opens the first insulating layer and the second insulating layer, and
the partition wall is electrically coupled to the conductive layer via a coupling member provided in the contact hole.

6. The electro-optical device according to claim 5, wherein
the partition wall is made of the same material as the coupling member.

7. The electro-optical device according to claim 1, wherein
the conductive layer is provided between light-emitting function layers adjacent to each other in plan view.

8. The electro-optical device according to claim 1, wherein
the contact hole is provided between light-emitting function layers adjacent to each other in plan view.

9. An electronic apparatus comprising the electro-optical device according to claim 1.
